(19) United States
(12) Patent Application Publication
(10) Pub. No.: US 2007/0133187 A1
(43) Pub. Date: Jun. 14, 2007

(54) Electronic device having a grounded structure

(75) Inventors: Gwo-Ching Lin, MiaoLi (TW); Wei-Jun Chen, MiaoLi (TW); Xiang Zhang, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/636,738

(22) Filed: Dec. 11, 2006

(30) Foreign Application Priority Data
Dec. 9, 2005 (TW) 94221479

(51) Int. Cl. H05K 7/14; H05K 7/18

(52) U.S. Cl. 361/799; 361/759

(57) ABSTRACT

An example electronic device (2) having a grounded structure includes a conductive bearing board (220) having at least one fixing pole (221); a circuit board (210) having at least one through hole (211) corresponding to the fixing pole, and a grounded layer (215) respectively formed at a peripheral region of the at least one through hole. The at least one fixing pole respectively fixed at the at least one through hole and contacts with the grounded layer. The electronic device has a simple structure, and it can be connected with a ground perfectly.

### FIELD OF THE INVENTION

The present invention relates to an electronic device, particularly to an electronic device having a grounded structure.

### GENERAL BACKGROUND

Generally, circuit board is a core element of a computer. The stability characteristic of the circuit board is important to the characteristics of the computer, which influences the stability characteristic of the computer. It's necessary to avoid the soldering point of the electronic elements on the circuit board from contacting with the housing of the computer and ground the circuit board for preventing the circuit board from short circuit.

For resolving the above question, a typical electronic device 1 is shown in FIG. 5. The electronic device 1 has a circuit board 110, a bearing board 120 and a plurality of elastic pieces 130, the circuit board 110 being fixed on the bearing board 120 through the plurality of elastic pieces 130.

The circuit board 110 has a plurality of through hole 112, a plurality of aligning holes 114, one side of each through hole 112 having two aligning holes 114, a plurality of mounting holes 116, each mounting hole 116 being positioned at another side of the through hole 112. The circuit board 110 further has a plurality of grounded pieces 118, each being adjacent the mounting holes 116.

The bearing board 120 has a plurality of conductive fixing poles 122 corresponding to the through holes 112, which each have a main body 1222, a head portion 1226, and a neck portion 1224 connecting the main body 1222 and the head portion 1226. The diameter of the neck portion 1224 is smaller than those of the head portion 1226 and the main body 1222, and the height of the neck portion 1224 is substantially equal to the sum of the thicknesses of circuit board 110 and the elastic piece 130. The main body 1222 can support the circuit board 110, the neck portion 1224 and the head portion 1226 can slide in the through holes 112.

Referring to FIG. 2, the elastic piece 130 is shown. The elastic piece 130 has a horizontal portion 132, a first bending portion 134, a second bending portion 136 and an extending portion 138, sequentially connecting end to end. The horizontal portion 132 and the first bending portion 134 define a fixing hole 135 thereat, which has a guiding hole 1352 and a block hole 1354 connecting each other. The heading portion 1226 of the fixing pole 122 can drill through the guiding hole 1352 and the neck portion 1224 can be blocked in the block hole 1354. The horizontal portion 132 further has two projects 1322 formed at a side (not labeled) defining the guiding hole 1352, far away from the first bending portion 134. The second bending portion 136 has an L-shaped vertical locating piece 139 having a horizontal tail end. The extending portion 138 has two convexes 1382 downward protruding, facing the circuit board 110.

In assembly, the locating piece 139 of the elastic piece 130 is firstly inserted into the mounting hole 116 of the circuit board 110, and the two projects 1322 of the elastic piece 130 are respectively inserted into the two locating holes 114 for positioning the elastic piece on the circuit board 110. The fixing pole 122 is firstly inserted into the through hole 112 of the circuit board 110 and the guiding hole 1352 of the elastic piece 130, wherein the circuit board 110 is supported at the main body 1222 of the fixing pole 122 and the head portion 1226 drills through the guiding hole 1352 of the horizontal portion 132. After that, the circuit board 110 is pushed relative to the bearing board 120 to let the fixing pole 122 slide from the guiding hole 1352 to the blocking hole 1354, and the first bending portion 134 of the elastic piece 130 is squeezed downwardly by the head portion 1226 of the fixing pole 122. Thus, the elastic piece 130 produces an elastic deformation to let the extending portion 138 extend outwardly and let the convexes 1382 of the extending portion 138 contact with the grounded piece 118. Thus, the electronic device 1 is grounded through the grounded piece 118, the elastic piece 130 and the fixing pole 122. Because the height of the neck portion 1224 is substantially equal to the sum of the thicknesses of the circuit board 110 and the elastic piece 130, when the neck portion 1224 of the fixing pole 122 slides into the block hole 1354, the circuit board 110 can be fixed on the bearing board 120 through sandwiching the circuit board 110 between the main body 1222 and the head portion 1226 of the fixing pole 122.

However, the electronic device 1 can not allow soldering point formed at a contacting region of the circuit board 110 and the elastic piece 130. Thus, space for depositing other electronic elements is decreased, which adds the designing difficult of the circuit board 110. In addition, because each fixing pole 122 needs an elastic piece 130 to mate, the electronic device 1 needs a plurality of elastic pieces 130, which makes the electronic device 1 complex.

What is needed, therefore, is a liquid crystal display that overcomes the above-described deficiencies.

### SUMMARY

In a preferred embodiment, an example electronic device having a grounded structure includes a conductive bearing board having at least one fixing pole; a circuit board having at least one through hole corresponding to the fixing pole, and a grounded layer respectively formed at a peripheral region of the at least one through hole. The at least one fixing pole respectively fixed at the at least one through hole and contacts with the grounded layer.

Other advantages and novel features will become more apparent from the following detailed description when taken in conjunction with the accompanying drawings.

### BRIEF DESCRIPTION OF THE DRAWINGS

FIG. 1 is a schematic view of an electronic device having a grounded structure according to a first embodiment of the present invention.

FIG. 2 is a partly enlarged view of a circled portion II in FIG. 1.

FIG. 3 is a schematic assembly view of the electronic device of FIG. 1.

FIG. 4 is a schematic view of an electronic device having a grounded structure according to a second embodiment of the present invention.

FIG. 5 is a schematic view of a conventional electronic device having an elastic piece.

FIG. 6 is a schematic, isometric view of the elastic piece of FIG. 5.

### DETAILED DESCRIPTION OF PREFERRED EMBODIMENTS

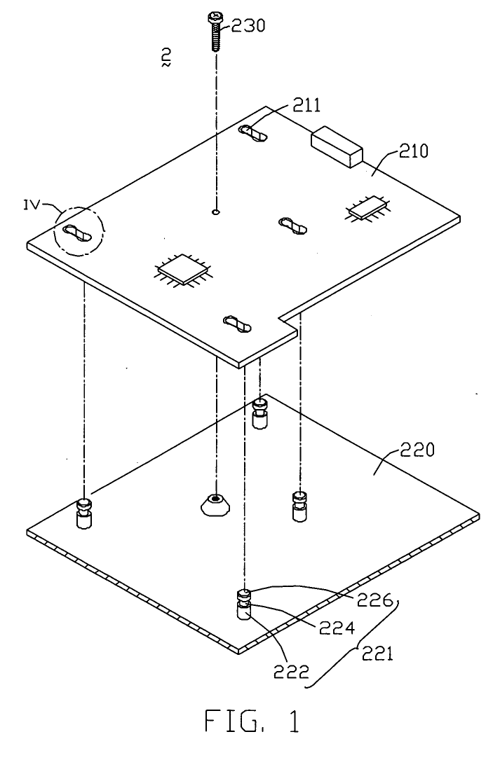

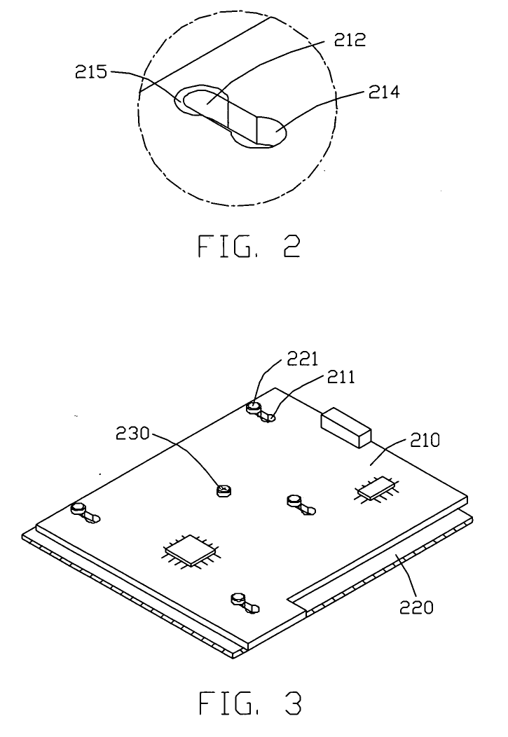

FIG. 1 shows a schematic view of an electronic device having a grounded structure according to a first embodiment of the present invention. FIG. 2 is a partly enlarged view of a circled portion II in FIG. 1. The electronic device 2 has a bearing board 220, a circuit board 210 positioned on the bearing board 220. The bearing board 220 is conductive and is grounded.

The circuit board 210 has at least one through hole 211, which each have a guiding hole 214 and a block hole 212. The circuit board 210 further has a grounded layer 215 formed at a peripheral region of the block hole 212, which the grounded layer 215 is made from soldering tin.

The bearing board 220 has at least one conductive fixing poles 221 corresponding to the through holes 211, which each have a main body 222, a head portion 226, and a neck portion 224 connecting the main body 222 and the head portion 226. The diameter of the neck portion 224 is smaller than those of the head portion 226 and the main body 222, and substantially equal to that of the block hole 212. The height of the neck portion 224 is substantially equal to the thicknesses of circuit board 210. The main body 222 can support the circuit board 210, the neck portion 224 and the head portion 226 can slide in the through hole 211.

Referring to FIG. 3, in assembly, the fixing pole 221 is firstly inserted into the through hole 211 of the circuit board 210, wherein the circuit board 210 is supported at the main body 222 of the fixing pole 221 and the head portion 226 of the fixing pole 221 drills through the through hole 211. After that, the circuit board 210 is pushed relative to the bearing board 220 to let the fixing pole 221 to slide from the guiding hole 214 to the blocking hole 212. Thus, the circuit board 210 is fixed on the bearing board 220 through blocking the neck portion 224 in the block hole 212. Because the height of the neck portion 224 is substantially equal to the thickness of the circuit board 210, when the neck portion 224 of the fixing pole 221 slides into the block hole 214, the circuit board 210 contacts with the grounded layer 215 formed at the peripheral region of the blocking hole 212. Thus, the circuit board 210 is grounded through the grounded layer 215 and the fixing pole 221. In addition, the electronic device 2 can further utilize a screw 230 to screw the circuit board 210 on the bearing board 220.

Comparing to the typical electronic device 1, the electronic device 2 just utilizes the conductive fixing pole 221 and the grounded layer 215 at the circuit board 210 to connect the grounded bearing board 220, which omits the elastic piece 130 of the typical electronic device 1 and simplify the structure of the electronic device 2. In addition, the contact region of the fixing pole 221 and the electronic board 210 is small, which adds the space for mounting others electronic elements and decreases the designing difficulty.

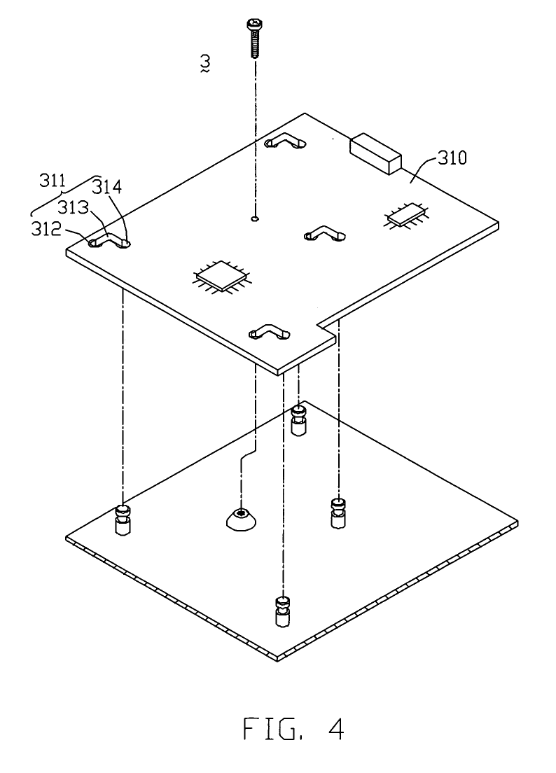

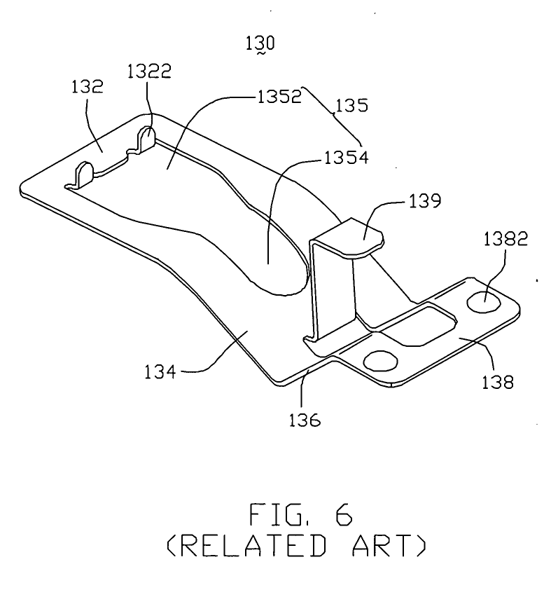

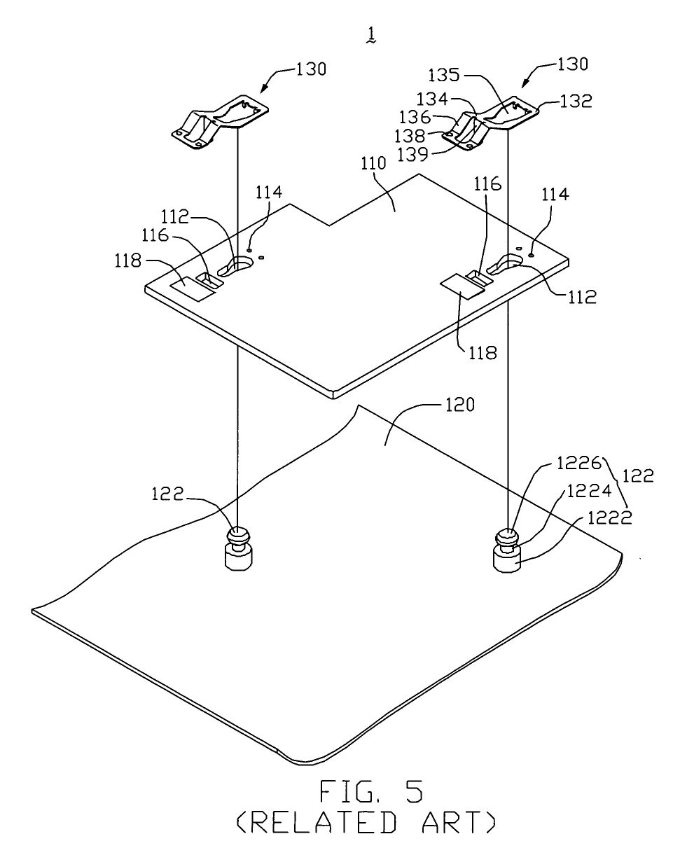

Referring to FIG. 4, an electronic device 3 according to the second embodiment of the present invention is shown. The electronic device 3 has a structure same to the electronic device 2 except that a through hole 311 of a circuit board 310 further has a connection hole 313 connecting a guiding hole 314 and a block hole 312. The connection hole 313 is a bending structure, such as L-shaped.

It is to be understood, however, that even though numerous characteristics and advantages of the present embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electronic device having a grounded structure, comprising:
a conductive bearing board, which comprises at least one fixing pole; and
a circuit board, which has at least one through hole corresponding to the fixing pole, a grounded layer respectively formed at a peripheral region of the at least one through hole;
wherein the at least one fixing pole respectively fixed at the at least one through hole and contacts with the grounded layer.

2. The electronic device as claimed in claim 1, wherein the through hole comprises a guiding hole and a block hole connecting with the guiding hole.

3. The electronic device as claimed in claim 2, wherein the grounded layer is formed at the peripheral of the block hole.

4. The electronic device as claimed in claim 2, wherein each fixing pole comprises a main body, a head portion, and a neck portion connecting the main body and the head portion, the diameter of the neck portion being smaller than those of the head portion and the main body.

5. The electronic device as claimed in claim 4, wherein the diameter of the neck portion is substantially equal to that of the block hole.

6. The electronic device as claimed in claim 2, wherein the through hole further has a connection hole connecting the guiding hole and the block hole.

7. The electronic device as claimed in claim 6, wherein the connection hole is a bending structure.

8. An electronic device having a grounded structure, comprising:
a conductive bearing board, which comprises at least one fixing pole; and
a circuit board, which has at least one through hole corresponding to the fixing pole and having a wide section and a narrow section, a grounded layer respectively formed at the narrow section;
wherein the at least one fixing pole is located in the narrow section and contacts the grounded layer.

9. The electrical device as claimed in claim 8, wherein said pole defines a neck dimensioned in compliance with the narrow section.
